(19) United States
(12) Patent Application Publication
(10) Pub. No.: US 2009/0327838 A1
(43) Pub. Date: Dec. 31, 2009

(54) MEMORY SYSTEM AND OPERATING METHOD FOR IT

(76) Inventors: Thomas Kottke, Ehningen (DE); Yorck von Collani, Beilstein (DE); Markus Ferch, Grossbottwar (DE)

Correspondence Address: KENYON & KENYON LLP, ONE BROADWAY, NEW YORK, NY, 10004, US

(21) Appl. No.: 11/989,383

(22) PCT Filed: Jul. 28, 2006
(86) PCT No.: PCT/EP2006/064768

§ 371 Date: May 13, 2009

(30) Foreign Application Priority Data
Aug. 30, 2005 (DE) 102005040916.4

(51) Int. Cl. H03M 13/05; G06F 11/10

(52) U.S. Cl. 714/764; 714/E11.043; 714/768; 714/E11.046

(57) ABSTRACT

A memory system includes a writable data memory and means for recognizing an error in a data word read out from the data memory, correcting the error, and storing the corrected data word at a new address in a free area of the data memory.

### FIELD OF THE INVENTION

The present invention relates to a memory system having a writable data memory and means for recognizing and correcting an error in a data word read out from the data memory as well as an operating method for such a memory system.

### BACKGROUND INFORMATION

Functional interference may occur in a writable data memory, which is manifested in that one or more bits of a stored data word spontaneously change their value. If such a data memory is used in a safety-relevant application, e.g., in an engine control unit of a motor vehicle or the like, it is absolutely necessary to recognize interference of this type and take suitable countermeasures to avoid dangerous malfunctions. In the simplest case, the countermeasures may include terminating an application which accesses the data memory in a predetermined way upon recognition of an error, so that a faulty data value is no longer accessed and maloperations because of the error are precluded. The application may then no longer be operated until the error is corrected in the data memory.

To avoid such an operational interruption, storing data words in a memory together with redundant information, on the basis of which not only may an error of the data word be recognized, but rather this error may also be corrected under certain circumstances, has come into consideration. Certain conventional encoding methods allow errors in the data word to be recognized and corrected, such as the Reed-Solomon or Hamming codes. Error correction codes may therefore be assumed to be known within the scope of the present description and are not explained in detail. If an application accesses a cell of the memory and establishes on the basis of the redundant information that the data word stored in the cell is faulty, a corrected data word may be provided to the application, and the application may be operated further without the danger of a maloperation.

The number of bit errors which may be corrected in a data word or in a block of data words encoded jointly using an error correction code is a function of the bit count of the redundant information produced for this data word or block. This means, for example, that if the bit count of the redundant information is sufficient to correct a single bit error in a data word or block, the operating capability of the application may be maintained only as long as no more than one bit error occurs in the affected data word or block. As soon as a second bit error occurs, correction is no longer possible, and the application must be terminated as described above.

However, memory errors tend to occur in groups, which means that the probability of the occurrence of an error in a memory bit is not equal everywhere, but rather is particularly high in the surroundings of an already existing error. To ensure continued usability of the memory even if a large number of bit errors occur closely adjacent to one another, a large quantity of redundant information is required, which increases the size of the required memory location and as a result the costs of the memory system.

### SUMMARY

An example method for operating a writable data memory or a memory system having such a data memory is provided according to the present invention, which allows insurance of a high degree of availability of the data memory and keeps the memory location required for storing redundant information small.

One advantage that may be achieved is that together with one data word, the redundant information assigned to this data word is read out from the data memory, it is checked on the basis of the redundant information whether the data word is faulty, and, if it is faulty, the data word is not only corrected, but rather is additionally written to a new address in a free area of the data memory. Because a correct version of the data word is thus again located at the new address, possible future errors occurring at this address may be corrected in the maximum number possible on the basis of the redundant information. The reliability of the data memory is therefore not impaired by the occurrence of individual bit errors as long as free memory location is available, into which the contents of defective memory cells may be moved. Because in most cases the new address will be far away from the original address of the data word recognized as faulty, the probability of the occurrence of further bit errors at the new address is less than at the original address, which further improves reliability.

The read sequence of the data words in the data memory is expediently altered to access the new address for reading the data word. This is necessary in particular if the data word represents a program instruction which must be executed in a predefined relationship with other instructions.

To alter the read sequence, at least one data word preceding the corrected data word in the read sequence may be written together therewith in the free area of the data memory, to thus be able to place, at the original memory location of the preceding data word, a reference, e.g., a jump instruction, to its new memory location.

After correcting the data word, a reference to a memory location, which follows the original memory location of the corrected data word, may be written to the free area.

Alternatively, the possibility exists of providing the free area in which the corrected data word is written in an address area following the address of the data word recognized as faulty, in that the contents of memory cells whose addresses follow those of the data word recognized as faulty are shifted.

Instead of shifting the memory cells following the data word recognized as faulty backward to provide the free area, the cells may also be provided, of course, in that the contents of memory cells whose addresses precede that of the data word recognized as faulty are shifted forward, in this case a reference to a memory location following the original memory location of the corrected data word being written in the free area following the corrected data word.

In both cases, it may be expedient if the shift of addresses significantly distant from the address of the data word recognized as faulty to addresses proximally adjacent thereto occurs progressively, so that data words do not have to be buffered outside the memory at a point at which a data loss is possible, for example, due to shutdown of the data processing system used by the memory system according to the present invention.

For the same purpose, shifting preferably includes copying a data word from an original address to a new address, followed by overwriting the original address using another data word after copying. It is thus ensured that every data word is present at least once in the memory at every instant.

If the set of data words contains a reference to a data word which has been moved into the free area, i.e., a jump instruction to this data word in the case of program instructions, for example, this reference is to be ascertained and adapted to the new address of the data word.

If data words before or after the data word recognized as faulty are shifted, references to shifted data words in the non-shifted data words and relative references to non-shifted data words in the shifted data words are also to be adapted to the shift to ensure further correct execution of the program instructions.

Because of the increased probability of the occurrence of errors in close proximity to one another, it is always expedient to check whether the data word recognized as faulty is part of a block having multiple faulty data words and possibly to correct the entire block and write it in the free area.

Further features and advantages of the present invention result from the following description of exemplary embodiments with reference to the attached figures of the drawings.

### BRIEF DESCRIPTION OF THE DRAWINGS

FIG. 1 shows a block diagram of a data processing system according to a first example embodiment of the present invention.

FIG. 2 illustrates the contents of a program memory of the data processing system from FIG. 1, in which an error has occurred.

FIG. 3 illustrates the contents of the program memory after correction of the error according to a first example embodiment of the method.

FIG. 4 illustrates the memory contents during the correction according to a second example embodiment of the method.

FIG. 5 illustrates the contents after completed correction according to the second example embodiment.

FIG. 6 shows a block diagram of a second example embodiment of the data processing system according to the present invention.

### DETAILED DESCRIPTION OF EXAMPLE EMBODIMENTS

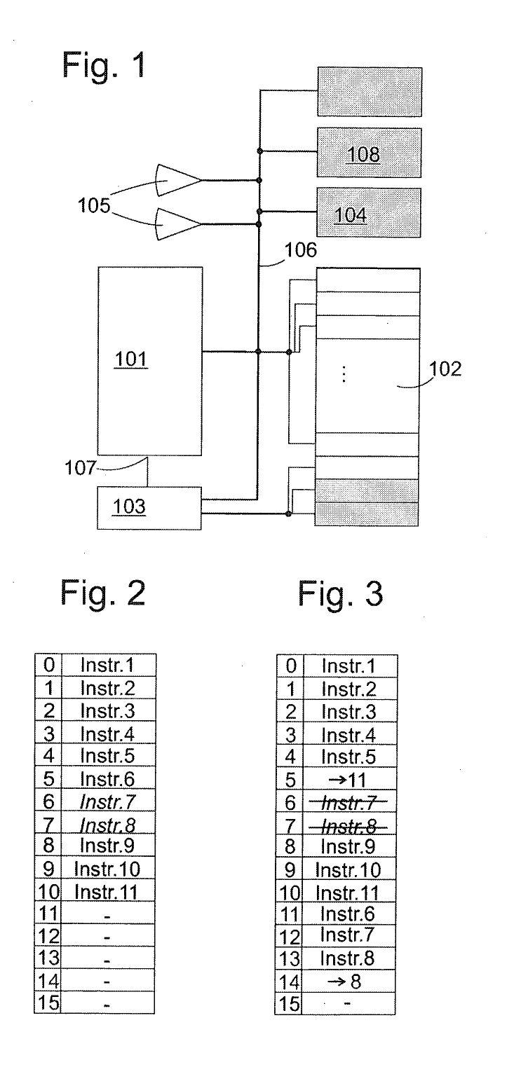

A motor vehicle control unit is illustrated in FIG. 1 as a block diagram as an example of a data processing system according to the present invention. It includes a processor 101, a flash memory 102, in which instructions of an application programmed to be executed by processor 101 are stored, a memory monitoring circuit 103 assigned to flash memory 102, a read/write memory 104, and diverse sensors 105 and actuators (not shown) for detecting and influencing operating parameters of a motor vehicle engine. Components 101 through 105 communicate via a shared data and addressing bus 106. The width of the data bus may be 16 bits, for example. The bit count of the memory cells of the flash memory is greater; it is 16+3 bits here, for example, a 16-bit data word containing a program instruction to be processed by processor 101 in each case and the remaining 3 bits containing redundant information obtained by Reed-Solomon coding of the data word, for example, which allows memory monitoring circuit 103 to recognize the presence of a bit error in the data word.

Memory monitoring circuit 103 is connected to an interrupt input 107 of processor 101 to trigger an interrupt of processor 101 if an error is recognized in a data word of flash memory 102. The application program is interrupted by this high-priority interrupt, and processor 101 reads out the redundant bits for the data word recognized as faulty and executes decoding to correct the faulty output data word from memory 102, and enters the address at which the faulty data word was read in a table. The application program is subsequently continued on the basis of the corrected data word.

Program instructions which are to be executed in the case of an interrupt of processor 101 triggered by monitoring circuit 103 may be stored in flash memory 102 like the application program. Because in this case the interrupt triggered by monitoring circuit 103 is no longer executable if the error or a further error is located in the program instructions of this interrupt, a further read-only memory 108 may be provided for the program instructions of the interrupt, which, in contrast to flash memory 102, does not have to be overwritable by processor 101 and in which the probability that a stored bit is faulty is less than in flash memory 102.

FIG. 2 schematically shows the usage of flash memory 102. In the figure 16 memory cells are shown (the number of the memory cells and the program instructions stored therein are multiple times greater in practice). To explain the present invention, it is assumed that of the 16 memory cells of flash memory 102 shown, cells 0 through 10 are occupied by program instructions Instr1 through Instr11 of an application to be executed by processor 101, and remaining memory cells 11 through 15 are unoccupied. A bit error has occurred in each of cells 6, 7, symbolized by italicized labeling Instr7 and Instr8.

According to a first example embodiment of the method according to the present invention, processor 101 reads the program instructions in flash memory 102, if no jump instructions are contained, in the sequence of rising addresses. If monitoring circuit 103 does not detect any errors in the read program instructions, they are executed by processor 101 as read. If monitoring circuit 103 recognizes a program instruction as faulty, i.e., for the first time with instruction Instr7 in the case shown in FIG. 2, monitoring circuit 103 outputs the above-mentioned high-priority interrupt request to processor 101, which causes the processor to execute the correction of the instruction incorrectly output by flash memory 102 itself on the basis of the associated redundant information.

During the execution of the high-priority interrupt, a second interrupt is triggered, whose priority is lower than that of the first interrupt and also than that of the specific time-critical parts of the application program and which causes processor 101 to perform a correction of the content of flash memory 102. This correction does not have to occur immediately after detection of the error in the flash memory, because the system still remains capable of running in that it corrects the errors in real time as described above. In relation to the concrete application example of an engine control unit, this means that a correction of the content of flash memory 102 does not have to be performed immediately after recognition of the error, but rather may be delayed until an interrupt of the application program required for error correction may be performed harmlessly, e.g., when the vehicle is at a standstill, in the afterrunning of an engine controller, or in an idle task.

After processor 101 has executed corrected instruction Instr7, in the present example, it addresses instruction Instr8, which is also assumed to be faulty. The sequence described above is repeated: the error is corrected during a brief interruption of the application program on processor 101, the corrected instruction is executed, and the second interrupt is triggered, using which the faulty instruction is later to be corrected.

If a lower-priority part of the application program is executed at a later time, i.e., when the application program may be interrupted long enough to execute the second interrupt and correct the error established in flash memory 102, a list of faulty memory cells exists due to the high-priority interrupts triggered upon each occurring error. In the exemplary case considered here, this list includes memory cells 6 and 7 having instructions Instr7 and Instr8.

According to a first example embodiment of the method according to the present invention, when executing the second interrupt, processor 101 writes instruction Instr6, which immediately precedes the instructions of faulty memory cells 6, 7, at the first free memory cell of memory 102, i.e., memory cell 11 in the present case, writes corrected instructions Instr7 and Instr8 to following memory cells 12, 13, and writes a jump instruction to cell 8, which follows the faulty cell, to memory cell 14. Instruction Instr6 in cell 5 is overwritten by a jump instruction to cell 11.

Defective memory cells 6, 7 no longer need to be accessed. Because the content of these memory cells has been corrected before the transfer into cells 12, 13, an error occurring in these new cells may also be corrected in the same way as described above, if sufficient free memory space is available for this purpose.

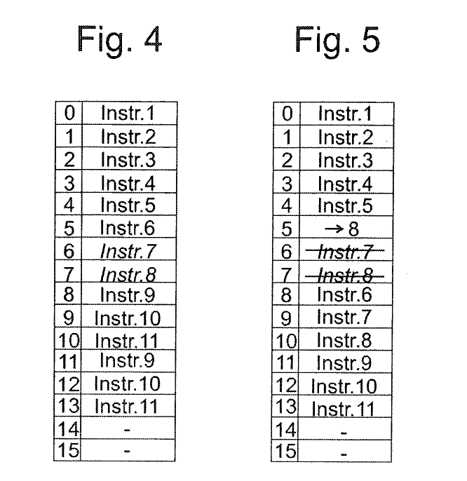

A second example embodiment of the method is explained on the basis of FIGS. 4 and 5. It is assumed as the starting situation that, as shown in FIG. 3, memory cells 6, 7 are defective. To take the defective memory cells out of operation, n=3 memory cells are needed. Number n is always 1 greater than the number of sequential defective cells, because an additional cell is needed to accommodate a jump instruction therein. Firstly, processor 101 copies the n last instructions of the application program including the associated redundant information from memory cells 8 through 10 into new, previously unoccupied memory cells 11 through 13, and the memory cells previously occupied by these instructions are released to be rewritten. The released memory cells are each overwritten by the contents of the n preceding memory cells, which are in turn released. This is repeated until defective memory cells 7, 8 and directly preceding memory cell 6 have also been read and transferred into the following memory cells, i.e., cells 8 through 10 here. A correction of the instructions read from cells 6 and 7 occurs, as described above for the application, automatically under the control of the high-priority interrupt, so that cells 9 and 10 contain instructions Instr7 and Instr8 and the associated redundant information in correct form. Memory cell 5 is now overwritten by a jump instruction to the new address of instruction Instr6, cell 8.

The example method described on the basis of FIGS. 4 and 5 assumes that a free memory area is present following the memory cells occupied by the application program, so that the entirety of the instructions which follows the faulty memory cells may be shifted to higher addresses. Of course, the similar possibility also exists of providing free memory cells in front of the cells occupied by the instructions of the application program and, in case of error, to shift instructions whose address is lower than that of the faulty cell or cells to lower addresses.

In practice, an application program has a large number of jump instructions. To ensure that the jump instructions remain correctly executable, it is necessary to identify them among the instructions of the application program and correct them if necessary. In the case of the embodiment of the method explained with reference to FIG. 3, a correction of jump instructions in the intact memory cells is only necessary if they have memory cells 6, 7, which have been recognized as defective, as the target. Jump instructions for which this applies are replaced by corresponding jump instructions to cells 12, 13.

In the case of the embodiment explained with reference to FIGS. 4, 5, in addition to the jump instructions oriented directly to faulty cells 6, 7, still further jump instructions have to be corrected. For absolute jump instructions, i.e., jump instructions which have a program count of a counter as an argument, it is checked whether this program count is above or below the first faulty memory cell, i.e., cell 6 here. If the jump target is below, the jump instruction remains unchanged, if it is above, it is increased by n. For relative jump instructions, i.e., those whose argument is added to the current program count of a counter to obtain the jump target, it is checked whether the jump instruction and its jump target are on the same side or on different sides of the faulty memory cells. In the first case, no correction is necessary, in the latter case, the jump width is increased by n.

Because the example method according to the present invention does not require correction of a detected error in flash memory 102 immediately after the detection, but rather the correction may be delayed until a suitable time, the method is well compatible with real-time applications which must fulfill specific tasks within predefined time limits. A delay which results from decoding the content of a faulty memory cell may nonetheless interfere with such an application. To minimize the probability that such a correction will be necessary, it may be expedient to read the program instructions stored in flash memory 102 successively in a starting phase of the application, in which no strict real-time requirements are yet to be fulfilled, to detect possible memory errors. If no memory error is detected, the application may subsequently go into operation normally; however, if a memory error is present, it is possible to correct it before the real-time requirements become stringent. In regard to the exemplary embodiment of an engine control unit, this means, for example, that a test for faulty memory cells is always performed when a user, for example, expresses his wish to start the engine by turning an ignition key, and an actual start of the engine is first controlled by the engine control unit after, if necessary, faulty memory cells have been corrected.

Performance in the afterrunning stage of the control unit is also expedient, i.e., in a limited time span after turning off the engine, in which the control unit still remains active.

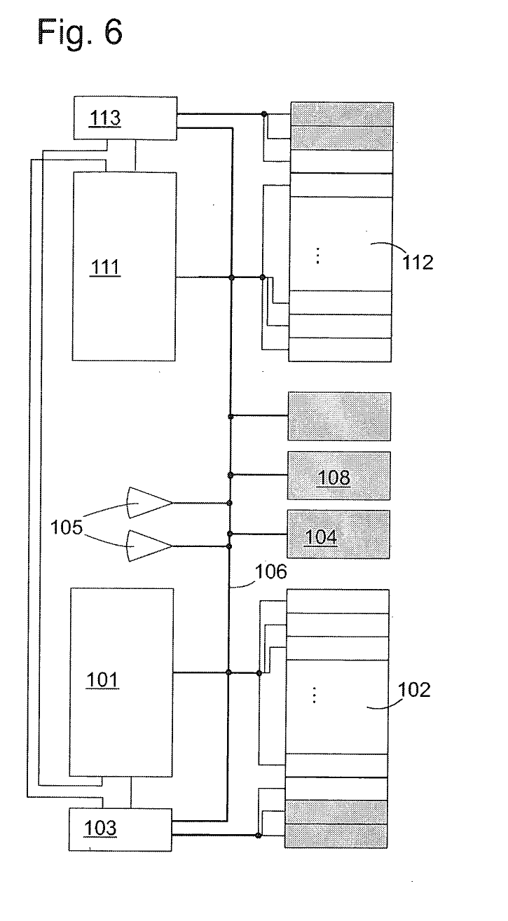

A second example embodiment of a data processing system, which offers further increased operational reliability in relation to the embodiment from FIG. 1, is shown in FIG. 6. In addition to the components described with reference to FIG. 1, this data processing system includes a second processor 111, which is capable, via bus 106 used jointly with processor 101 or also via a second independent bus, of accessing flash memory 102 of processor 101. A second flash memory 112 is assigned to processor 111, which contains an application program for processor 111. While in this example embodiment memory monitoring circuit 103 assigned to flash memory 102 is connected only to processor 101 to temporarily interrupt it in case of a faulty output of flash memory 102, it triggers an interrupt at second processor 111 which causes it to decode the faulty output data word, transfer a corrected data word to processor 101, and to note the address of the faulty data word in a list and trigger a second interrupt, which performs the correction of memory 102 on the basis of the list at a suitable later time in a similar way as described above with reference to FIG. 3 or to FIGS. 4, 5. In a symmetrical way, processor 101 processes interrupts which a memory monitoring circuit 113 triggers because of an error in flash memory 112 of second processor 111. Errors which occur in the instructions of the first interrupt in one of both memories 102 or 112 may no longer result in a crash of the system, because they are corrected by interrupt instructions stored in the particular other memory.

The second interrupt may be handled in the example embodiments described above by the same processor 101 or 111 which also handled the first interrupt. However, it is also possible to have it handled by an external processor, which communicates with the data processing system of FIG. 1 or FIG. 6 via a network connection, a mobile wireless connection, or the like.

A further possible version is to design monitoring circuit 103 in such a way that it not only executes the recognition of an error in a data word output by memory 102, but rather also its decoding and correction, without using processor 101 assigned to memory 102. The temporary interruption of processor 101 which is necessary to prevent it from accepting a data word output incorrectly on bus 106 may occur here in that monitoring circuit 103 interrupts a clock signal supplied to processor 101 as long as it needs to in order to correct the faulty instruction output by memory 102 and output it in turn correctly on bus 106. Breakdown of the decoding as a result of a faulty stored interrupt instruction in memory 102 is also precluded here. This example embodiment has the advantage of being able to correct errors not only in an instruction memory, but rather also in a parameter memory.

The present invention is also applicable to other types of data memories. Thus, for example, a hard drive may be used as a memory, on which useful data are stored in blocks together with redundant information assigned to each block and, in the case that an error is recognized on the basis of the redundant information, the affected block is corrected, stored again at another point of the hard drive surface, and a block which precedes the faulty block in the read sequence of a file to which the blocks belong is provided with a reference to the new memory location of the corrected block. The corrected block may in turn receive a reference to a following block in the read sequence, so that the blocks may still be read according to the sequence, even if they are not recorded in a contiguous location on the disk surface.

1-13. (canceled)

14. A method for operating a writable data memory which contains a set of data words to be read in a read sequence, and redundant information, comprising:
reading, together with a data word, redundant information assigned to the data word;
checking, based on the redundant information whether the data word is faulty; and
if the data word is faulty, correcting the data word, wherein the corrected data word is written to a new address in a free area of the data memory.

15. The method as recited in claim 14, further comprising:
altering the read sequence to access the new address for reading the data word.

16. The method as recited in claim 15, wherein, together with the corrected data word, at least one data word preceding the corrected data word in the read sequence is written to the free area of the data memory, and a reference to a new memory location is entered at an original memory location of the at least one preceding data word.

17. The method as recited in claim 16, wherein a reference to a memory location following a memory location of the corrected data word is written to the free area after the corrected data word.

18. The method as recited in claim 16, wherein, after a data word has been recognized as faulty, the free area is provided in an address area following an address of the data word recognized as faulty, in that contents of memory cells, whose addresses follow that of the data word recognized as faulty, are shifted.

19. The method as recited in claim 15, wherein, after a data word has been recognized as faulty, the free area is provided in an address area preceding an address of the data word recognized as faulty, in that contents of memory cells whose addresses precede that of the data word recognized as faulty are shifted, and a reference to a memory location following an original memory location of the corrected data word is written in the free area following the corrected data word.

20. The method as recited in claim 19, wherein the shift of addresses at a great distance from the address of the data word recognized as faulty to addresses closely adjacent to the address of the data word recognized as faulty, occurs progressively.

21. The method as recited in claim 19, wherein the shift includes copying a data word from an original address to a new address and overwriting the original address with a different data word after the copying.

22. The method as recited in claim 18, wherein the data words contain program instructions, and references to each data word written into the free area are adapted.

23. The method as recited in claim 22, wherein absolute and relative instructions referencing shifted data words are adapted to the shift in the non-shifted data words and relative instructions to non-shifted data words are adapted to the shift in the shifted data words.

24. The method as recited in claim 14, further comprising:
checking whether the data word recognized as faulty is part of a block having multiple faulty data words, if so, the entire block is corrected and written to the free area.

25. A memory system, comprising:
a writable data memory;
a reorganizer adapted to recognize and correct an error in a data word read out from the data memory; and
an arrangement adapted to store the corrected data word at a new address in a free area of the data memory.

26. A data processing system, comprising:
a memory system including a writable data memory, a recognizer adapted to recognize and correct an error in a data word read out from the data memory, and an arrangement adapted to store the corrected data word at a new address in a free area of the data memory; and
a first and a second processor, wherein the data memory contains program instructions to be executed by the first processor, and the second processor forms the arrangement adapted to store the corrected data word at the new address.
